(19) United States
(12) Patent Application Publication
(10) Pub. No.: US 2026/0190297 A1
(43) Pub. Date: Jul. 2, 2026

(54) Server Information Handling System Airflow Management System

(71) Applicant: Dell Products L.P., Round Rock, TX (US)

(72) Inventors: Eduardo Escamilla, Round Rock, TX (US); Juan Gonzalez, Round Rock, TX (US); Robert Proulx, Holden, MA (US)

(21) Appl. No.: 19/008,415

(22) Filed: Jan. 2, 2025

(51) Int. Cl. H05K 7/20

(52) U.S. Cl. CPC H05K 7/20736; H05K 7/20145

(57) ABSTRACT

An airflow management system for an information handling system. The airflow management system includes a fan system; and, an airflow management device, the airflow management device including an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with an airflow management system.

In one embodiment, the invention relates to an airflow management device for use with an information handling system, comprising: an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

In another embodiment, the invention relates to an airflow management system for an information handling system comprising: a fan system; and, an airflow management device, the airflow management device comprising: an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

In another embodiment, the invention relates to a system comprising: a chassis; a plurality of components contained within the chassis; and, an airflow management system, the airflow management system comprising a fan system; and, an airflow management device, the airflow management device comprising: an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a perspective view of an airflow management system.

FIGS. 5A, 5B, 5C and 5D, generally referred to as FIG. 5, show views of an airflow management device.

FIGS. 6A, 6B and 6C, generally referred to as FIG. 6, show views of an alternate airflow management device.

### DETAILED DESCRIPTION

Various aspects of the present disclosure include an appreciation that server type information handling system structural designs are becoming increasingly large as a function of growing component size and increasing heat loads within the system. Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system. Various aspects of the present disclosure include an appreciation that arrays of components often require additional structural support.

Various aspects of the present disclosure include an appreciation that GPU modules are often configured to conform to form factor standards. Various aspects of the present disclosure include an appreciation that the card electromechanical (CEM) form factor standard is one such form factor standard. Various aspects of the disclosure include an appreciation that it is known to provide information handling systems with baseboard systems such as peripheral component interconnect express (PCIe) type baseboard systems.

Various aspects of the present disclosure include an appreciation that cooling an array of components can often require careful airflow management. Various aspects of the present disclosure include an appreciation that cooling an array of components can often present a number of information handling system design challenges. These design challenges are especially present in systems which are designed with a plurality of components such as a plurality of GPUs. These design challenges are also especially present in systems which are designed with an array of AICs, such as in systems which are designed to support artificial intelligence (AI) workloads.

Various aspects of the present disclosure include an appreciation that airflow designs often include an airflow source such as a fan system. Various aspects of the present disclosure include an appreciation that component arrays often have an associated airflow inlet size. Various aspects of the present disclosure include an appreciation that with many known information handling system designs, the airflow source outlet size and the component array airflow inlet size are often mismatched.

Various aspects of the present disclosure include an appreciation that it would be desirable to provide an airflow management system which matches an airflow source outlet size and a component array airflow inlet size. Various aspects of the present disclosure include an appreciation that it would be desirable to provide an airflow management system which optimizes airflow from an airflow source across an array of components. Various aspects of the present disclosure include an appreciation that it would be desirable to provide an airflow management system which provides structural support for an array of components.

A system and method are disclosed for providing a power system of a server type information handling system with an airflow management system. the airflow management system 150 includes a fan system, an airflow management device, or a combination thereof. In certain embodiments, the airflow management device includes an airflow shroud component, a component support bracket, or a combination thereof.

In certain embodiments, the airflow management system handles airflow mismatch while providing structural support for an array of components. In certain embodiments, the airflow management system includes a fan system. In certain embodiments, the fan system includes two rows of six fans. In certain embodiments, the array of components includes eight components. In certain embodiments, the airflow management optimizes airflow between the mis matched fan system airflow outlet size and a component array airflow inlet size. In certain embodiments, the airflow shroud component directs airflow to individual components of an array of components. In certain embodiments, the component support bracket provides structural support for components of the array of components.

In certain embodiments, shapes of edges of the airflow shroud component are tuned by airflow streamlining. In certain embodiments, shapes of edges of the airflow shroud component are tuned to reduce airflow vortices.

In certain embodiments, the airflow shroud component is configured to include vertical transition vanes. In certain embodiments, the vertical transition vanes help with airflow management associated with a mis matched fan system fan configurations and a component array configuration (e.g., the transition from a 2×6 fan configuration and a 1×8 component array configuration.

Such an airflow management system advantageously reduces the pressure drop penalty between mis matched fan system airflow outlet size and a component array airflow inlet size. Such an airflow management system advantageously provides optimized factory integration between the fan system and the array of components. Such an airflow management system advantageously provides accessible field service. The pressure drop reduction also allows for more system airflow for a given fan input power.

Such an airflow management system advantageously provides an airflow management system which matches an airflow source outlet size and a component array airflow inlet size. Such an airflow management system advantageously provides an airflow management system which optimizes airflow from an airflow source across an array of components. Such an airflow management system advantageously provides an airflow management system which provides structural support for an array of components.

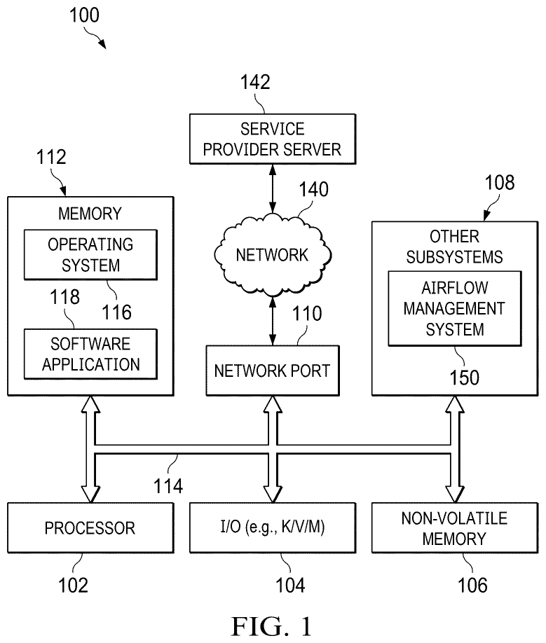

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, the other subsystems 108 include an airflow management system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the airflow management system 150 is part of an airflow management environment which includes a plurality of components and an airflow management system 150 coupled to the plurality of components. In certain embodiments, the plurality of components are arranged as an array of components. In certain embodiments, the plurality of components include a plurality of GPU modules. In certain embodiments, the plurality of GPU modules are designed to support artificial intelligence (AI) workloads.

In certain embodiments, the airflow management system 150 includes a fan system, an airflow management device, or a combination thereof. In certain embodiments, the airflow management device includes an airflow shroud component, a component support bracket, or a combination thereof.

In certain embodiments, the airflow management system 150 handles airflow mismatch while providing structural support for an array of components. In certain embodiments, the fan system includes two rows of six fans. In certain embodiments, the array of components includes eight components. In certain embodiments, the airflow management optimizes airflow between the mis matched fan system airflow outlet size and a component array airflow inlet size. In certain embodiments, the airflow shroud component directs airflow to individual components of an array of components. In certain embodiments, the component support bracket provides structural support for components of the array of components.

In certain embodiments, shapes of edges of the airflow shroud component are tuned by airflow streamlining. In certain embodiments, shapes of edges of the airflow shroud component are tuned to reduce airflow vortices.

In certain embodiments, the airflow shroud component is configured to include vertical transition vanes. In certain embodiments, the vertical transition vanes help with airflow management associated with a mismatched fan system fan configurations and a component array configuration (e.g., the transition from a 2×6 fan configuration and a 1×8 component array configuration).

Such an airflow management system advantageously reduces the pressure drop penalty between mis matched fan system airflow outlet size and a component array airflow inlet size. Such an airflow management system advantageously provides optimized factory integration between the fan system and the array of components. Such an airflow management system advantageously provides accessible field service. The pressure drop reduction also allows for more system airflow for a given fan input power.

Such an airflow management system advantageously provides an airflow management system which matches an airflow source outlet size and a component array airflow inlet size. Such an airflow management system advantageously provides an airflow management system which optimizes airflow from an airflow source across an array of components. Such an airflow management system advantageously provides an airflow management system which provides structural support for an array of components.

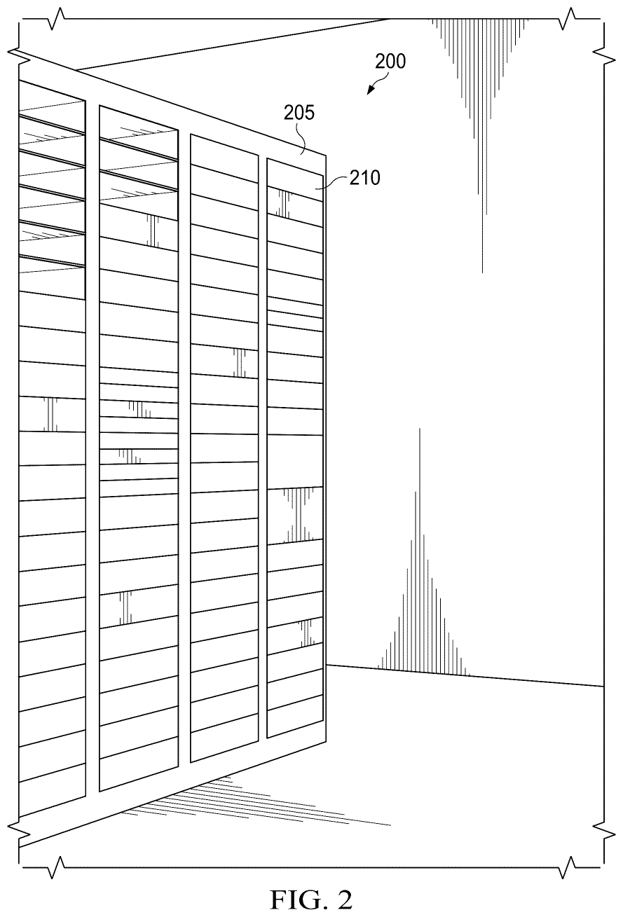

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit, and a 4 U rack unit. In general, a 1 U rack unit is substantially (i.e., +/−20%) 1.75″ high, a 2 U rack unit is substantially (i.e., +/−20%) 3.5″ high, and a 4 U rack height is substantially (i.e., +/−20%) 7.0″ high.

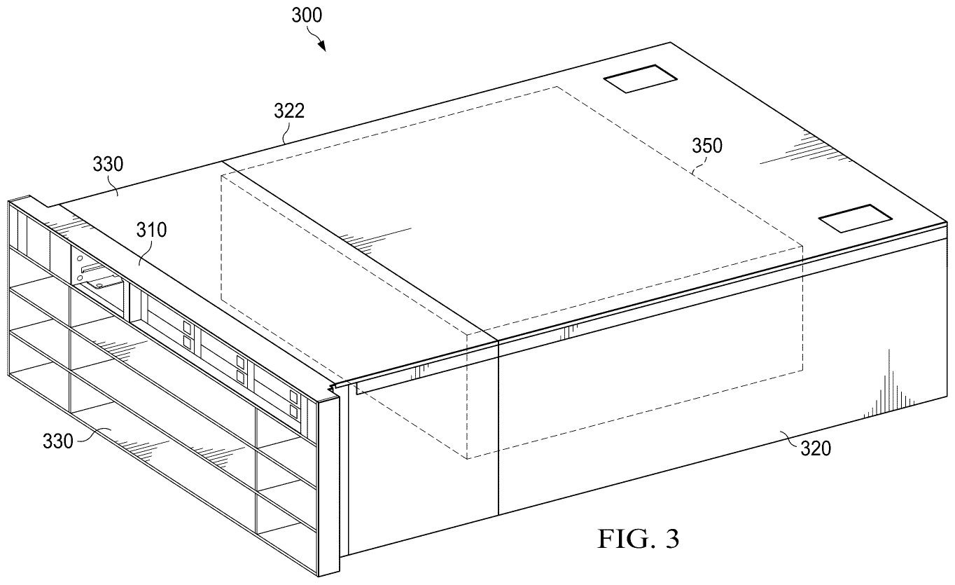

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the server system 300 includes an airflow management environment 350.

In certain embodiments, the airflow management environment 350 includes a plurality of components and an airflow management system. In certain embodiments, the plurality of components are arranged as an array of components. In certain embodiments, the plurality of components includes a plurality of GPUs. In certain embodiments, the plurality of GPUs are designed to support artificial intelligence (AI) workloads. In certain embodiments, airflow management system of the airflow management environment 350 corresponds to airflow management system 150.

In certain embodiments, the airflow management system of the airflow management environment 350 includes a fan system, an airflow management device, or a combination thereof. In certain embodiments, the airflow management device includes an airflow shroud component, a component support bracket, or a combination thereof.

In certain embodiments, the airflow management system handles airflow mismatch while providing structural support for an array of components. In certain embodiments, the fan system includes two rows of six fans. In certain embodiments, the array of components includes eight components. In certain embodiments, the airflow management optimizes airflow between the mis matched fan system airflow outlet size and a component array airflow inlet size. In certain embodiments, the airflow shroud component directs airflow to individual components of an array of components. In certain embodiments, the component support bracket provides structural support for components of the array of components.

In certain embodiments, shapes of edges of the airflow shroud component are tuned by airflow streamlining. In certain embodiments, shapes of edges of the airflow shroud component are tuned to reduce airflow vortices.

In certain embodiments, the airflow shroud component is configured to include vertical transition vanes. In certain embodiments, the vertical transition vanes help with airflow management associated with a mis matched fan system fan configurations and a component array configuration (e.g., the transition from a 2×6 fan configuration and a 1×8 component array configuration).

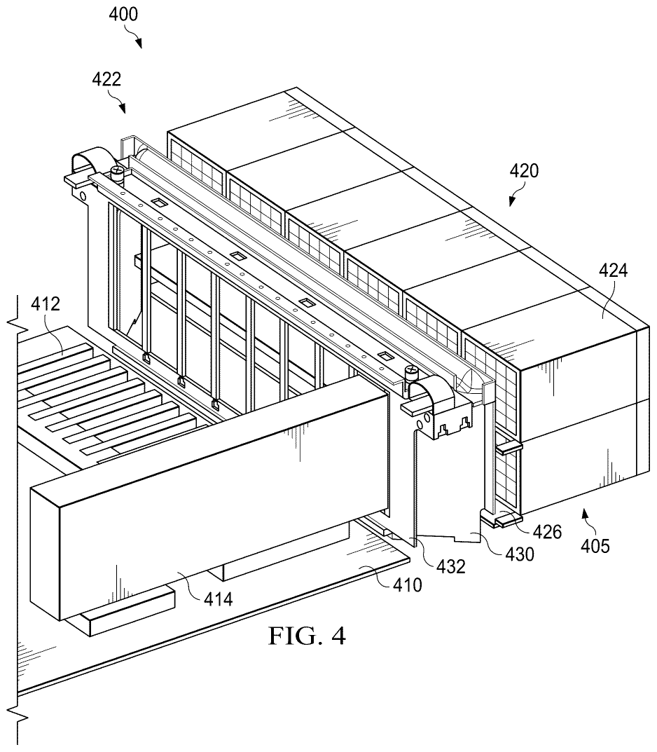

FIG. 4 shows a perspective view of airflow management environment 400 having an airflow management system 405. In certain embodiments, the airflow management environment 400 includes the airflow management system 405, a system board 410, a component coupled to the system board, or a combination thereof. In certain embodiments, the airflow management system 405 corresponds to airflow management system 150.

In certain embodiments, the system board 410 includes a system circuit board. In certain embodiments, the system circuit board includes one or more of a motherboard, a planar circuit board, a high performance module circuit board, and a baseboard circuit board. In certain embodiments, the system board 410 includes a plurality of slots 412. In certain embodiments, one or more of the plurality of slots 412 includes a CEM type slot. In certain embodiments, the plurality of slots 412 are arranged in parallel on the system board 405. In certain embodiments, the plurality of slots 412 are arranged to mount a plurality of components 414 (one of which is shown in FIG. 4). In certain embodiments, the plurality of components 414 are arranged as an array of components. In certain embodiments, the plurality of components includes a plurality of GPUs. In certain embodiments, the plurality of GPUs are designed to support artificial intelligence (AI) workloads.

In certain embodiments, the array of components 414 includes eight components mounted in parallel or sixteen components mounted in parallel. In certain embodiments, a side of the array of components 414 is configured as a component array airflow inlet area. In certain embodiments, the component array airflow inlet area has a corresponding component array airflow inlet size. In certain embodiments, the component array airflow inlet area is substantially (i.e., +/−20%) rectangularly shaped.

In certain embodiments, the airflow management system 405 includes a fan system 420. In certain embodiments, the fan system 420 includes a plurality of fans 424, a fan control board 426, or a combination thereof. In certain embodiments, the plurality of fans 424 are arranged in two rows of six fans each. In certain embodiments, the fans are arranged in two parallel rows of six fans. In certain embodiments, a bottom row of fans 424 is mounted to the fan control board 426. In certain embodiments, an upper row of fans 424 is mounted to the bottom row of fans 424. In certain embodiments, the fan system 420 defines a fan system airflow outlet area. In certain embodiments, the fan system airflow outlet area has a corresponding fan system airflow outlet size. In certain embodiments, the fan system airflow outlet area is substantially (i.e., +/−20%) rectangularly shaped.

In certain embodiments, the airflow management system 405 optimizes airflow between the mis matched fan system airflow outlet area size and a component array airflow inlet area size. In certain embodiments, the fan system airflow outlet size is larger than the component array airflow inlet size. In certain embodiments, the airflow management system 405 includes a fan system airflow inlet and a component array airflow outlet. In certain embodiments, the fan system airflow inlet has a corresponding fan system airflow inlet area. In certain embodiments, the component array airflow outlet has a corresponding component array airflow outlet area. In certain embodiments, the fan system airflow inlet area is larger than the component array airflow outlet area. In certain embodiments, the fan system airflow inlet area is substantially (i.e., +/−20%) the same size as the as the fan system airflow outlet area. In certain embodiments, the component array airflow outlet area is substantially (i.e., +/−20%) the same size as the component array airflow inlet. In certain embodiments, the airflow management system 405 optimizes airflow between the fan system airflow inlet size and the component array airflow outlet.

In certain embodiments, the airflow management system 405 includes an airflow management device 422. In certain embodiments, the airflow management device 422 includes an airflow shroud component 430, a component support bracket 432, or a combination thereof. In certain embodiments, the airflow shroud component 430 handles airflow mismatch. In certain embodiments, the airflow shroud component 430 directs airflow to airflow inlets of individual components 414 of the array of components. In certain embodiments, the component support bracket 432 provides structural support for the array of components 414. In certain embodiments, the component support bracket 432 provides structural support for one side of the array of components 414. In certain embodiments, the component support bracket 432 retains the array of components 414. In certain embodiments, shapes of edges of the airflow shroud component 430 are tuned by airflow streamlining. In certain embodiments, shapes of edges of the airflow shroud component 430 are tuned to reduce airflow vortices.

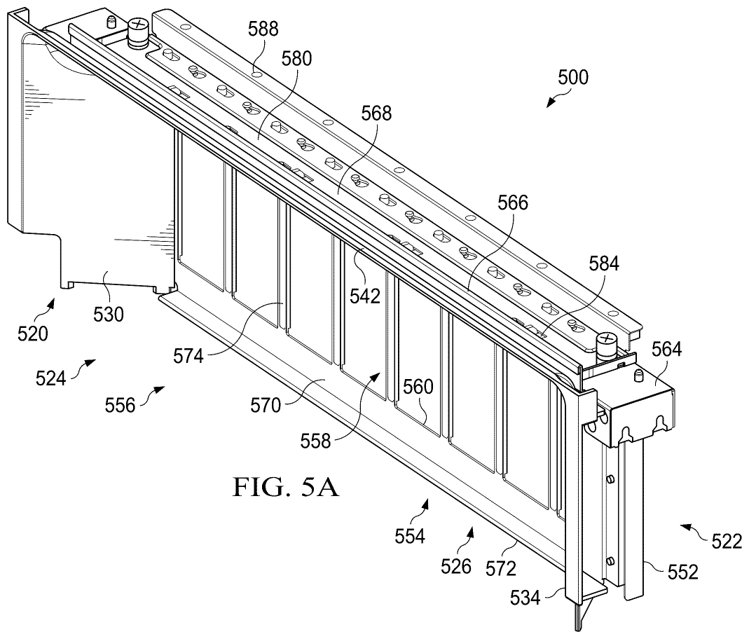

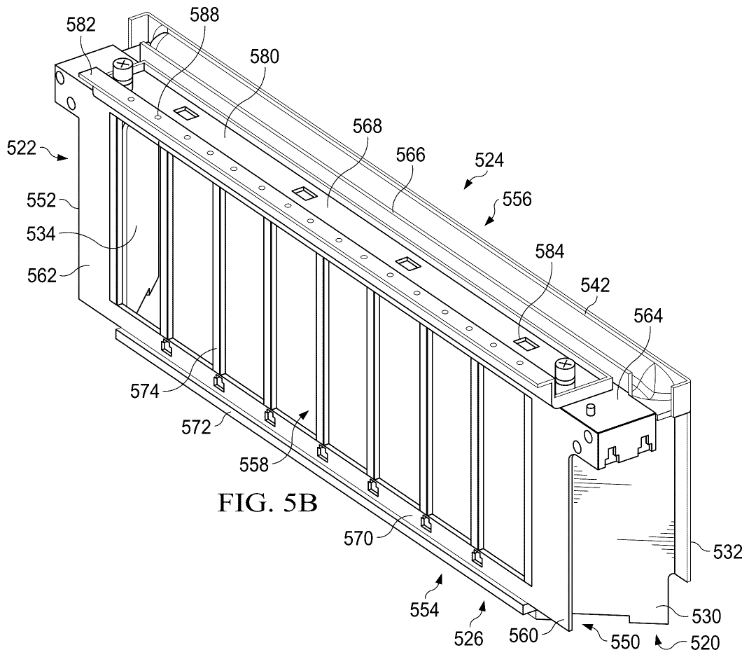

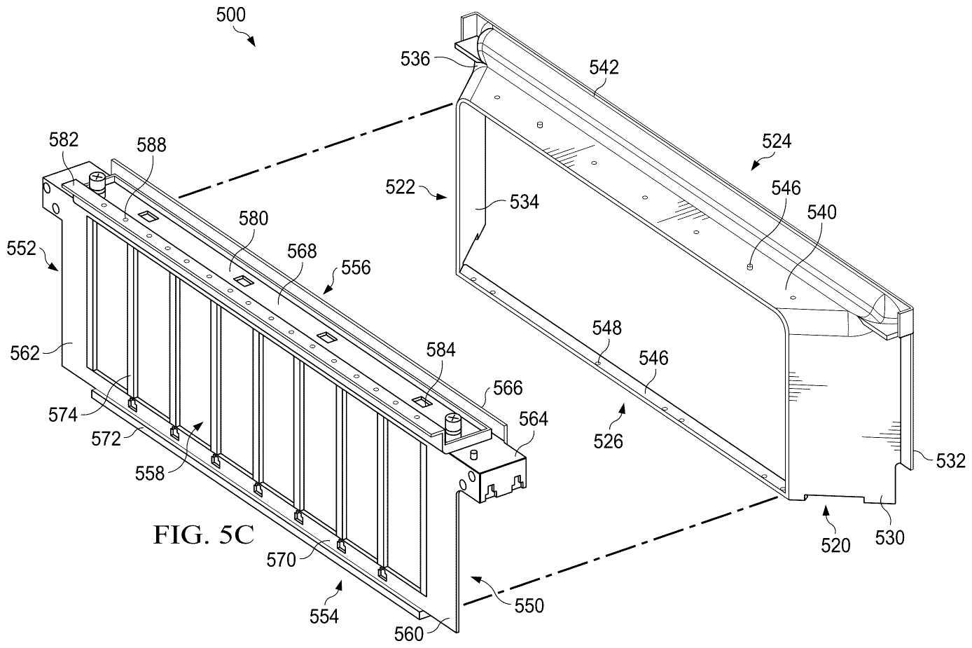

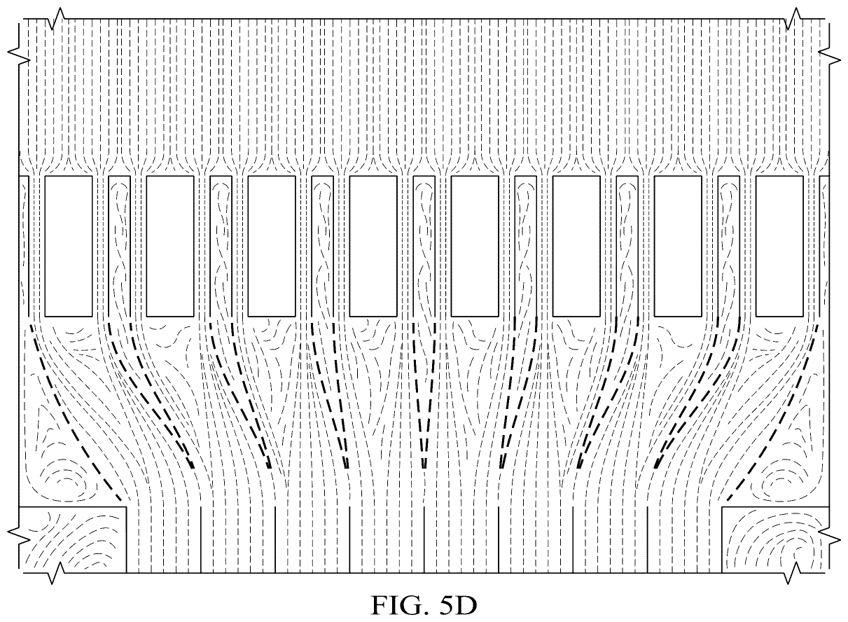

FIGS. 5A, 5B, 5C and 5D, generally referred to as FIG. 5, show views of an airflow management device 500. More specifically, FIG. 5A shows a front perspective view of an airflow management device 500. FIG. 5B shows a front perspective view of an airflow management device 500. FIG. 5C shows an exploded rear perspective view of an airflow management device 500. FIG. 5D shows a diagrammatic representation of airflow within an airflow management device 500. In certain embodiments, the airflow management device 500 corresponds to the airflow management device of airflow management system 150.

In certain embodiments, the airflow management device 500 includes an airflow shroud component 510, a component support bracket 512, or a combination thereof. In certain embodiments, the airflow shroud component 510 handles airflow mismatch. In certain embodiments, the airflow shroud component 510 directs airflow to airflow inlets of individual components of an array of components. As used herein, an airflow shroud component refers to a device which surrounds and directs airflow.

In certain embodiments, the component support bracket 512 provides structural support for an array of components. In certain embodiments, the component support bracket 512 provides structural support for one side of the array of components. In certain embodiments, the component support bracket 512 retains one side of the array of components. In certain embodiments, shapes of edges of the airflow shroud component 510 are tuned by airflow streamlining. In certain embodiments, shapes of edges of the airflow shroud component 430 are tuned to reduce airflow vortices.

In certain embodiments, the airflow shroud component 510 includes a first side portion 520, a second side portion 522, a top portion 524 and a bottom portion 526. In certain embodiments, the first side portion 520, the second side portion 522, the top portion 524 and the bottom portion 526 are constructed from a single piece of material. In certain embodiments, the first side portion 520, the second side portion 522, the top portion 524 and the bottom portion 526 are constructed from a single piece of plastic. In certain embodiments, the first side portion 510 includes a first side wall 530, a fan system mating flange 532 or a combination thereof. In certain embodiments, the first side wall 530 is angled from the fan system airflow inlet to the component array airflow outlet. In certain embodiments, the first side wall 530 includes a flat interior surface for directing airflow between the fan system airflow inlet and the component array airflow outlet. In certain embodiments, the first side wall 530 is shaped to reduce airflow vortices between the airflow management device 500 and the array of components. In certain embodiments, the shape of the first side wall 530 is tuned by airflow streamlining. In certain embodiments, the shape of the first side wall 530 is tuned to reduce airflow vortices. In certain embodiments, the second side portion 522 includes a second side wall 534, a fan system mating flange 536 or a combination thereof. In certain embodiments, the second side wall 534 is angled from the fan system airflow inlet to the component array airflow outlet. In certain embodiments, the second side wall 534 includes a flat interior surface for directing airflow between the fan system airflow inlet and the component array airflow outlet. In certain embodiments, the second side wall 534 is shaped to reduce airflow vortices between the airflow management device 500 and the array of components. In certain embodiments, the shape of the second side wall 534 is tuned by airflow streamlining. In certain embodiments, the shape of the second side wall 534 is tuned to reduce airflow vortices.

In certain embodiments, the top portion 524 includes a top wall 540, a top fan system mating flange 542, or a combination thereof. In certain embodiments, the top wall 540 defines a plurality of fastener apertures 544. In certain embodiments, the bottom portion 526 includes a bottom wall 546. In certain embodiments, the bottom wall 546 defines a plurality of fastener apertures 548.

In certain embodiments, the component support bracket 512 includes a first side portion 550, a second side portion 552, a top portion 554, a bottom portion 556 and an interior portion 558. In certain embodiments, the first side portion 550, the second side portion 552, at least some of the top portion 554, the bottom portion 556 and the interior portion 558 are constructed from a single piece of material. In certain embodiments, the first side portion 550, the second side portion 552, at least some of the top portion 554, the bottom portion 556 and the interior portion 558 are constructed from a single piece of metal.

In certain embodiments, the first side portion 550 includes a first side wall 560. In certain embodiments, the second side portion 552 includes second side wall 562. In certain embodiments, the top portion 554 includes a top wall 564, a top flange 566, a component support element 568, or a combination thereof. In certain embodiments, the component support element 568 of the top portion 554 is constructed from a different piece of material than the material from which the rest of the component support bracket is constructed. In certain embodiments, the bottom portion 556 includes a bottom wall 570 and a bottom flange 572. In certain embodiments, the interior portion 558 includes a plurality of vertical strips 574. In certain embodiments, each vertical strip 574 extends between the top wall 564 and the bottom wall 570.

In certain embodiments, the component support element 568 includes a horizontal structural member 580 and a component flange 582. In certain embodiments, the component flange 582 is substantially L-shaped. In certain embodiment, the horizontal structural member 580 defines a plurality of fastener apertures 584. In certain embodiments, the component flange 582 defines a plurality of component fastener apertures.

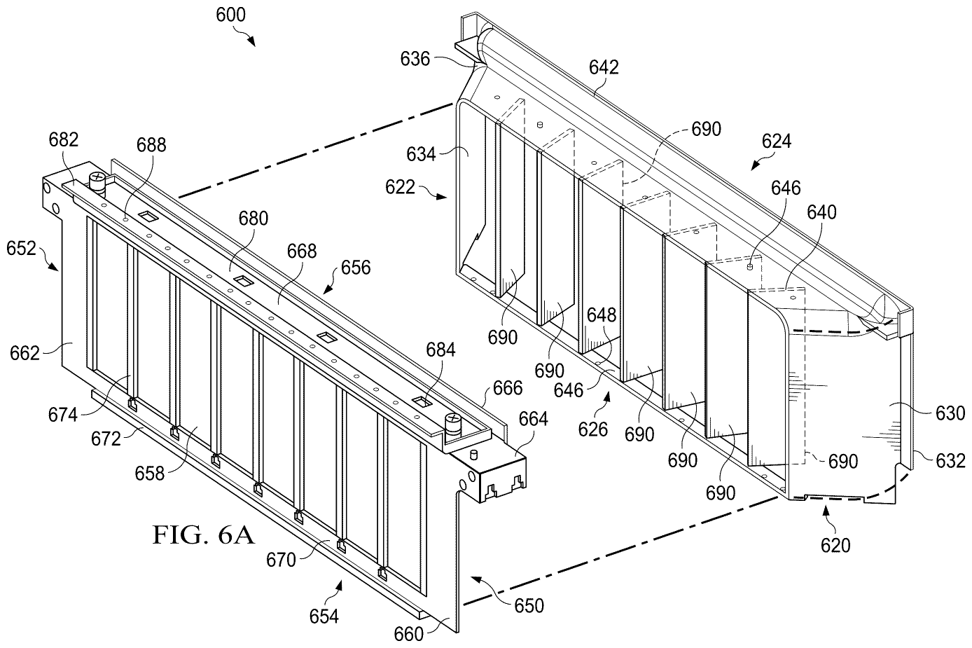

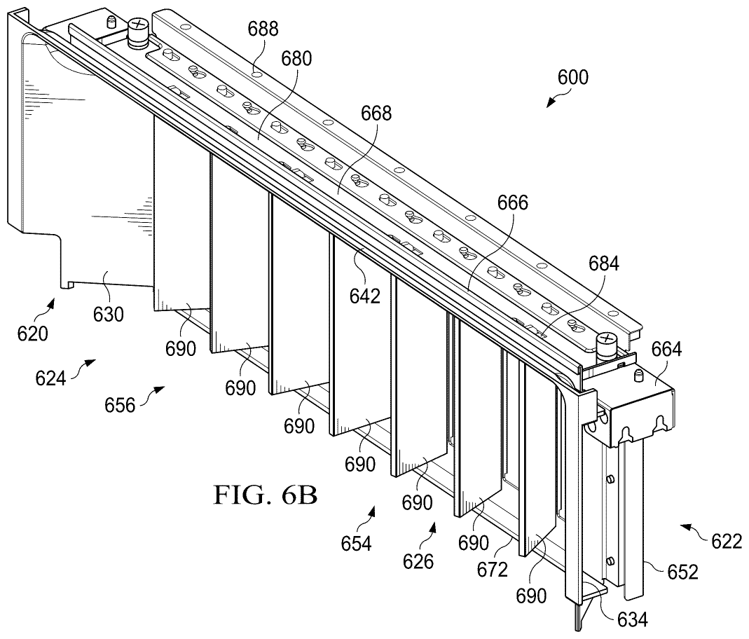

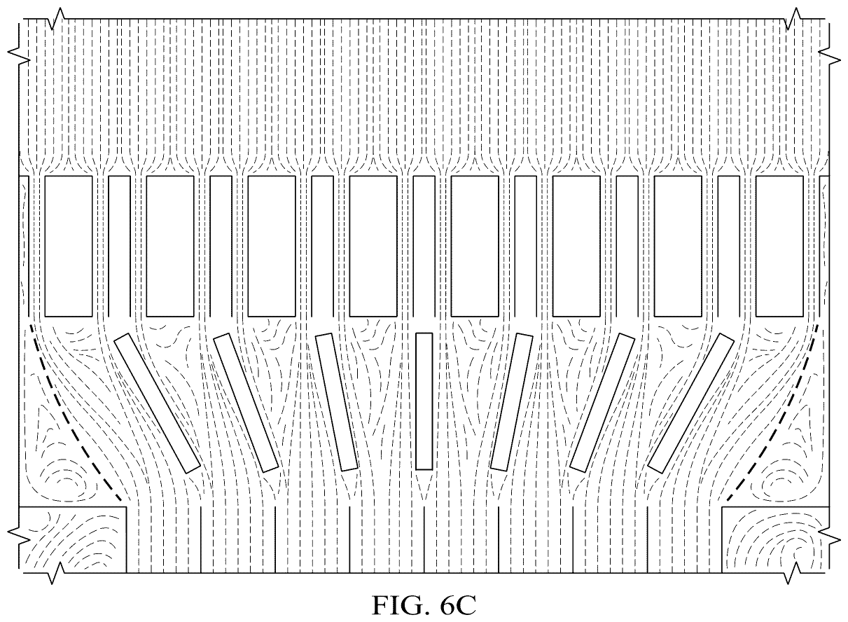

FIGS. 6A, 6B and 6C, generally referred to as FIG. 6, show views of an alternate airflow management device. More specifically, FIG. 6A shows an exploded rear perspective view of an airflow management device 600. FIG. 6B shows a rear perspective view of an airflow management device 600. FIG. 6C shows a front perspective view of an airflow management device 600. In certain embodiments, the airflow management device 600 corresponds to the airflow management device of airflow management system 150.

In certain embodiments, the airflow management device 600 includes an airflow shroud component 610, a component support bracket 612, or a combination thereof. In certain embodiments, the airflow shroud component 610 handles airflow mismatch. In certain embodiments, the airflow shroud component 610 directs airflow to airflow inlets of individual components of an array of components. As used herein, an airflow shroud component refers to a device which surrounds and directs airflow.

In certain embodiments, the component support bracket 612 provides structural support for an array of components. In certain embodiments, the component support bracket 612 provides structural support for one side of the array of components. In certain embodiments, the component support bracket 612 retains one side of the array of components. In certain embodiments, shapes of edges of the airflow shroud component 610 are tuned by airflow streamlining. In certain embodiments, shapes of edges of the airflow shroud component 430 are tuned to reduce airflow vortices.

In certain embodiments, the airflow shroud component 610 includes a first side portion 620, a second side portion 622, a top portion 624 and a bottom portion 626. In certain embodiments, the first side portion 620, the second side portion 622, the top portion 624 and the bottom portion 626 are constructed from a single piece of material. In certain embodiments, the first side portion 620, the second side portion 622, the top portion 624 and the bottom portion 626 are constructed from a single piece of plastic. In certain embodiments, the first side portion 610 includes a first side wall 630, a fan system mating flange 632 or a combination thereof. In certain embodiments, the first side wall 630 is angled from the fan system airflow inlet to the component array airflow outlet. In certain embodiments, the first side wall 630 includes a flat interior surface for directing airflow between the fan system airflow inlet and the component array airflow outlet. In certain embodiments, the first side wall 630 is shaped to reduce airflow vortices between the airflow management device 600 and the array of components. In certain embodiments, the shape of the first side wall 630 is tuned by airflow streamlining. In certain embodiments, the shape of the first side wall 630 is tuned to reduce airflow vortices. In certain embodiments, the second side portion 622 includes a second side wall 634, a fan system mating flange 636 or a combination thereof. In certain embodiments, the second side wall 634 is angled from the fan system airflow inlet to the component array airflow outlet. In certain embodiments, the second side wall 634 includes a flat interior surface for directing airflow between the fan system airflow inlet and the component array airflow outlet. In certain embodiments, the second side wall 634 is shaped to reduce airflow vortices between the airflow management device 600 and the array of components. In certain embodiments, the shape of the second side wall 634 is tuned by airflow streamlining. In certain embodiments, the shape of the second side wall 634 is tuned to reduce airflow vortices.

In certain embodiments, the top portion 624 includes a top wall 640, a top fan system mating flange 642, or a combination thereof. In certain embodiments, the top wall 640 defines a plurality of fastener apertures 644. In certain embodiments, the bottom portion 626 includes a bottom wall 646. In certain embodiments, the bottom wall 646 defines a plurality of fastener apertures 648.

In certain embodiments, the component support bracket 612 a first side portion 650, a second side portion 652, a top portion 654, a bottom portion 656 and an interior portion 658. In certain embodiments, the first side portion 650, the second side portion 652, at least some of the top portion 654, the bottom portion 656 and the interior portion 658 are constructed from a single piece of material. In certain embodiments, the first side portion 650, the second side portion 652, at least some of the top portion 654, the bottom portion 656 and the interior portion 658 are constructed from a single piece of metal.

In certain embodiments, the first side portion 650 includes a first side wall 660. In certain embodiments, the second side portion 652 includes second side wall 662. In certain embodiments, the top portion 654 includes a top wall 664, a top flange 666, a component support element 668, or a combination thereof. In certain embodiments, the component support element 668 of the top portion 654 is constructed from a different piece of material than the material from which the rest of the component support bracket is constructed. In certain embodiments, the bottom portion 656 includes a bottom wall 670 and a bottom flange 672. In certain embodiments, the interior portion 658 includes a plurality of vertical strips 674. In certain embodiments, each vertical strip 674 extends between the top wall 664 and the bottom wall 670.

In certain embodiments, the component support element 668 includes a horizontal structural member 680 and a component flange 682. In certain embodiments, the component flange 682 is substantially L-shaped. In certain embodiments, the horizontal structural member 680 defines a plurality of fastener apertures 684. In certain embodiments, the component flange 682 defines a plurality of component fastener apertures.

In certain embodiments, the airflow shroud component 610 is configured to include vertical transition vanes 690. In certain embodiments, the vertical transition vanes 690 help with airflow management associated with a mismatched fan system fan configurations and a component array configuration (e.g., the transition from a 2×6 fan configuration and a 1×8 component array configuration). In certain embodiments, the airflow shroud component 610 includes a number of vertical transition vanes 690 based upon a number of components in an array. For example, in an 8-component array configuration, the airflow shroud component 610 includes seven vertical transition vanes 690. In a 16-component array configuration, the airflow shroud component 610 includes fifteen vertical transition vanes 690.

Other embodiments are within the following claims. For example, a single power division and identification circuit could be associated with more than two component circuits by adding additional component detection circuit along with additional associated signal paths.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An airflow management device for use with an information handling system, comprising:
an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

2. The airflow management device of claim 1, wherein:
the airflow shroud component includes a first side portion, a second side portion, a top portion and a bottom portion, the first side portion, the second side portion, the top portion and the bottom portion being constructed from a single piece of material.

3. The airflow management device of claim 2, wherein:
the first side portion includes a first side wall, the first side wall being shaped to reduce airflow vortices between the airflow management device and component array; and,
the second side portion includes a second side wall, the second side wall being shaped to reduce airflow vortices between the airflow management device and component array.

4. The airflow management device of claim 1, further comprising:
a component support bracket, the component support bracket being attached to the airflow outlet of the airflow shroud component, the component support bracket providing structural support for an array of components.

5. The airflow management device of claim 4, wherein:
the component support bracket includes a first side portion, a second side portion, a top portion, a bottom portion and an interior portion, the first side portion, the second side portion, at least some of the top portion, the bottom portion and the interior portion being constructed from a single piece of material.

6. The airflow management device of claim 5, wherein:
the top portion of the component support bracket includes a component support element, the component support element having a component flange, the component flange retaining one side of the array of components.

7. An airflow management system for an information handling system comprising:
a fan system; and,
an airflow management device, the airflow management system comprising
an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

8. The airflow management system of claim 7, wherein:
the airflow shroud component includes a first side portion, a second side portion, a top portion and a bottom portion, the first side portion, the second side portion, the top portion and the bottom portion being constructed from a single piece of material.

9. The airflow management system of claim 8, wherein:
the first side portion includes a first side wall, the first side wall being shaped to reduce airflow vortices between the airflow management device and component array; and,
the second side portion includes a second side wall, the second side wall being shaped to reduce airflow vortices between the airflow management device and component array.

10. The airflow management system of claim 7, wherein the airflow management device further comprises:
a component support bracket, the component support bracket being attached to the airflow outlet of the airflow shroud component, the component support bracket providing structural support for an array of components.

11. The airflow management system of claim 10, wherein:
the component support bracket includes a first side portion, a second side portion, a top portion, a bottom portion and an interior portion, the first side portion, the second side portion, at least some of the top portion, the bottom portion and the interior portion being constructed from a single piece of material.

12. The airflow management system of claim 11, wherein:
the top portion of the component support bracket includes a component support element, the component support element having a component flange, the component flange retaining one side of the array of components.

13. A system comprising:
a chassis;
a plurality of components contained within the chassis; and,
an airflow management system, the airflow management system comprising
a fan system; and,
an airflow management device, the airflow management system comprising
an airflow shroud component, the airflow shroud component having a fan system airflow inlet and a component array airflow outlet, the fan system airflow inlet having a corresponding fan system airflow inlet area, the component array airflow outlet having a corresponding component array airflow outlet area, the fan system airflow inlet area being larger than the component array airflow outlet area, the airflow shroud component optimizing airflow between the fan system airflow inlet and the component array airflow outlet.

14. The system of claim 13, wherein:
the airflow shroud component includes a first side portion, a second side portion, a top portion and a bottom portion, the first side portion, the second side portion, the top portion and the bottom portion being constructed from a single piece of material.

15. The system of claim 14, wherein:
the first side portion includes a first side wall, the first side wall being shaped to reduce airflow vortices between the airflow management device and component array; and,
the second side portion includes a second side wall, the second side wall being shaped to reduce airflow vortices between the airflow management device and component array.

16. The system of claim 14, wherein the airflow management device further comprises:
a component support bracket, the component support bracket being attached to the airflow outlet of the airflow shroud component, the component support bracket providing structural support for an array of components.

17. The system of claim 16, wherein:
the component support bracket includes a first side portion, a second side portion, a top portion, a bottom portion and an interior portion, the first side portion, the second side portion, at least some of the top portion, the bottom portion and the interior portion being constructed from a single piece of material.

18. The system of claim 17, wherein:
the top portion of the component support bracket includes a component support element, the component support element having a component flange, the component flange retaining one side of the array of components.
